(19) United States
(12) Patent Application Publication
(10) Pub. No.: US 2007/0080752 A1
(43) Pub. Date: Apr. 12, 2007

(54) Apparatus for low noise and jitter injection in test applications

(76) Inventor: Stephen William Smith, San Jose, CA (US)

Correspondence Address: STEPHEN W. SMITH, 2302 LAVA DRIVE, SAN JOSE, CA, 95133, US

(21) Appl. No.: 11/542,025

(22) Filed: Oct. 3, 2006

Related U.S. Application Data
(60) Provisional application No. 60/726,968, filed on Oct. 11, 2005.
(60) Provisional application No. 60/765,363, filed on Feb. 6, 2006.

(51) Int. Cl. H03L 7/00

(52) U.S. Cl. 331/16

(57) ABSTRACT

A method and apparatus for a low noise low jitter signal source is provided. A Voltage Controlled Oscillator (VCO) is configured as part of a phase locked Loop (PLL) with a reference clock, a loop filter and a method of offsetting the Tune Voltage input to the Voltage Controlled Oscillator (VCO) to achieve low phase noise. A method and apparatus for precisely controlled jitter injection into a high speed data or clock signals is provided. Using IQ modulation techniques comprising an IQ modulator, by synchronously controlling the IQ modulator inputs precisely controlled phase shift for jitter injection are produced. This can also be used with the low noise low jitter signal source described herein.

### CROSS-REFERENCE TO RELATED INVENTIONS

I claim the benefit of the following provisional patents:

Appl No. 60/726,968 Switched offset phase locked loop for low noise applications

Appl No. 60/765,363: Clock jitter injection using IQ modulation techniques

### FIELD OF THE INVENTION

The field of the invention relates to automatic test equipment, both automatic and manual, more specifically to the testing of components, devices or modules where accuracy, cost or size of the equipment is critical to lowering the cost of test and giving the best possible yield.

### BACKGROUND

Electronic devices are often tested using automatic test equipment (ATE). Generally, the tester includes a computer system that coordinates and runs the tests, and a testing apparatus. The testing apparatus usually includes a test head, into which the device under test (DUT) is placed, a base unit or server which houses power supplies, cooling, control circuitry and any instrumentation that is too bulky to fit into the test-head. Unfortunately for Radio Frequency (RF) or Serial Datacom Testing (SERDES) the test equipment is usually bulky and expensive. The prior art solution for this have been that either, no testing is done at all which is a very risky approach, that a golden device/module is used to test which provides a functional go/no go result but no information on how close to the limits the device is performing, likewise this is true for loopback testing where the transmit portion of the device is connected to the receive portion of the device. For true parametric measurements the current options are both costly and bulky. A large 19″ rack-mounted Radio Frequency (RF) signal generator for RF semiconductor/module testing which is necessary to give low phase noise and for SERDES low jitter. This box would include phase modulation for Radio Frequency (RF) applications but would not be useable for Serial Datacom Testing (SERDES) jitter injection so would require significant external circuitry to form a complete solution. Jitter injection is also a problem for higher data rates because the prior art approach shifts the clock edges in time domain which at higher data rates becomes more difficult and costly due to semiconductor device limitations. Another approach for Serial Datacom Testing (SERDES) is to use the proprietary test that is commercially available. This equipment necessarily uses extremely exotic custom semiconductor devices which are very expensive making the complete solution cost-prohibitive for high volume testing.

The purpose of this invention is to overcome all of the problems stated in providing a very low cost Radio Frequency (RF) signal source that is spectrally pure, low in phase noise for Radio Frequency (RF) testing and also low in phase jitter for Serial Datacom Testing. Additionally the second part to this invention is an apparatus to add controlled jitter injection to the Radio Frequency (RF) signal source using off-shelf standard Radio Frequency (RF) and microwave components and techniques thus significantly simplifying the problem and lowering the cost.

### SUMMARY AND OBJECTS OF THE INVENTION

This Invention contains a way of providing a small, low phase noise (RF) signal source with a wide tuning range for test and measurement or Automatic Test Equipment (ATE) systems. This Invention contains a way of providing a small, low phase jitter clock signal source with a wide tuning range for digital or high speed serial data test and measurement or Automatic Test Equipment (ATE) systems.

This Invention contains a way for providing a small low cost jitter injection into a data or clock source for test and measurement or Automatic Test Equipment (ATE) systems.

This invention enables the test equipment to in close proximity to the devices being tested thus improving the reliability of any test results.

### BRIEF DESCRIPTION OF DRAWINGS

The present invention is illustrated by way of example, not by way of limitation, in figures of the accompanying drawings and in which like reference numerals refer to similar elements in which:

FIG. 1 illustrates a block diagram of one embodiment of the low noise Radio frequency (RF) signal source in which the present invention may be implimented in a conventional Tester.

FIG. 2 illustrates a block diagram of one embodiment of using Radio frequency (RF) signal signal source in which the present invention may be implimented where parts are mounted in the testhead

FIG. 3 illustrates a block diagram of one embodiment of using the Radio frequency (RF) signal source in which the present invention may be implimented as an independent instrument.

FIG. 4 illustrates a block diagram of one embodiment of the IQ jitter injection signal source in which the present invention may be implimented in a conventional Tester.

FIG. 5 illustrates a block diagram of another embodiment of the IQ jitter injection signal source in which the present invention may be implimented in a conventional Tester.

FIG. 6 illustrates a block diagram of one embodiment of using IQ jitter injection signal signal source in which the present invention may be implimented where parts are mounted in the testhead

FIG. 7 illustrates a block diagram of another embodiment of using IQ jitter injection signal signal source in which the present invention may be implimented where parts are mounted in the testhead

FIG. 8 illustrates a block diagram of one embodiment of a switched offset Phase-Locked Loop (PLL) using a switched offset Voltage Controlled Oscillator (VCO).

FIG. 9 illustrates a block diagram of another embodiment of a switched offset Phase-Locked Loop (PLL) using a switched offset Voltage Controlled Oscillator (VCO).

FIG. 10 illustrates a block diagram of one embodiment of a switched offset Phase-Locked Loop (PLL) using a sliding rail supply for the Voltage Controlled Oscillator (VCO) offset.

FIG. 11 illustrates a block diagram of another embodiment of a switched offset Phase-Locked Loop (PLL) using a sliding rail supply for the Voltage Controlled Oscillator (VCO) offset.

FIG. 12 Illustrates one embodiment of a switch offset Voltage Controlled Oscillator (VCO).

FIG. 13) Illustrates one embodiment of basic IQ clock jitter injection block diagram

FIG. 14) Illustrates one embodiment of IQ clock jitter injection with digital modulation

### DETAILED DESCRIPTION

The Low Jitter/Phase noise signal source and using IQ modulation to inject jitter into a digital waveform described in this patent is entirely unique and original.

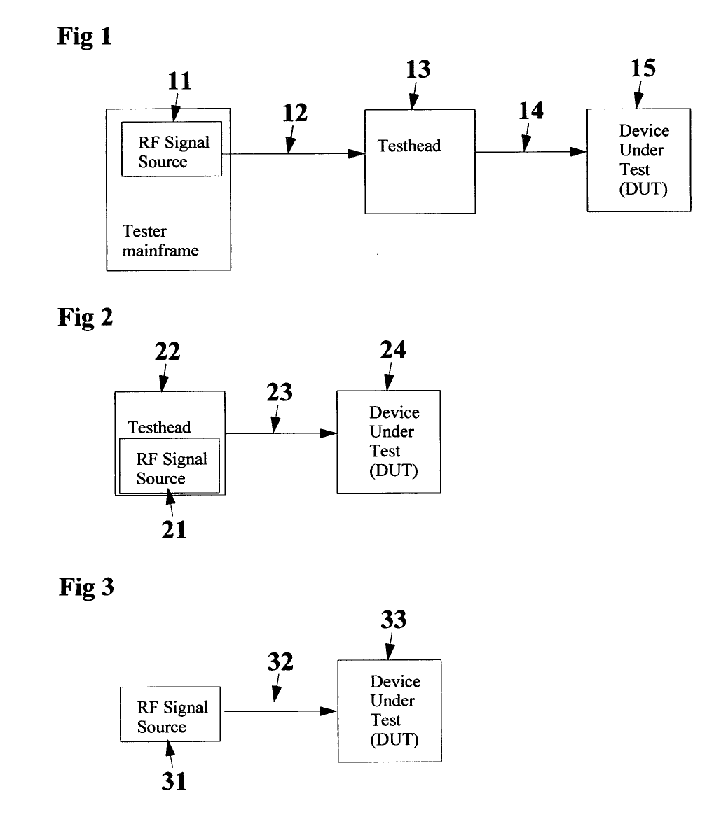

FIG. 1 shows a typical Tester architecture in which a low-noise Radio Frequency (RF) signal source (11) could be used. The RF signal source produces a low noise spectrally pure signal which is passed via a Radio Frequency (RF) coaxial cable (12) to the Testhead (13) then via a shorter Radio Frequency (RF) coaxial cable or connectors (14) to the device under test (DUT) (15).

FIG. 2 shows The Radio Frequency (RF) Signal Source (21) residing directly in the testhead (22) then connected directly via shorter Radio Frequency (RF) coaxial cable or connectors (23) to the device under test (DUT) (24).

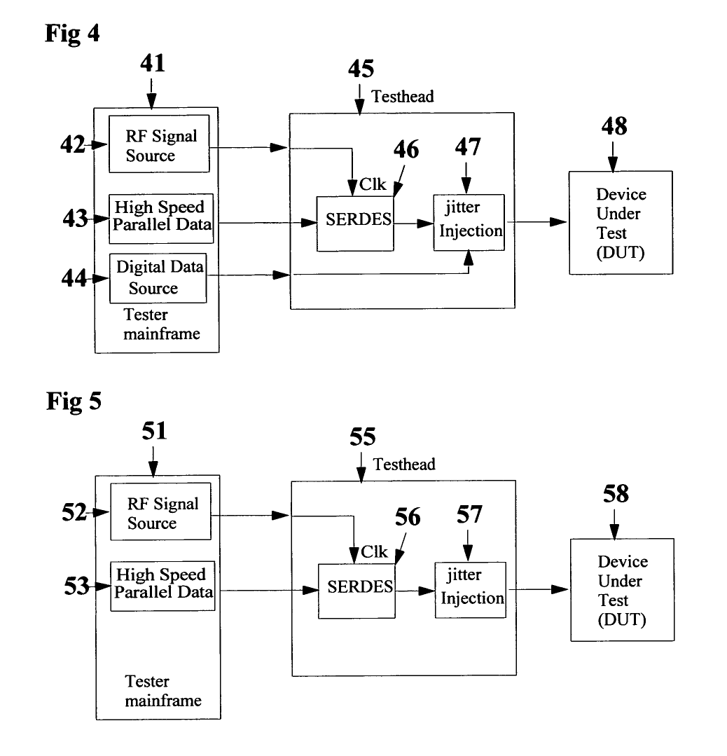

FIG. 3 shows The Radio Frequency (RF) Signal Source (31) connected directly via shorter Radio Frequency (RF) coaxial cable or connectors (32) to the device under test (DUT) (33). FIG. 4 shows a Serial data Test System comprising the Radio Frequency (RF) Signal Source (42), which is used as a low-jitter clock for the Parallel to Serial data converter (SERDES)(46) a high speed parallel data source (43) which is used to provide a high speed programmable parallel data stream which determines the final serial bit pattern in the Parallel to Serial data converter (SERDES). A digital data source (44) can be used to controls the IQ jitter injection circuit (47), or one possible variant the IQ jitter injection circuit (47) would be that it could generate it's own jitter patterns internally. In this example the Radio Frequency (RF) Signal Source (42), the high speed parallel data source (43), digital data source (44) all reside in the mainframe (41), whereas Parallel to Serial data converter (SERDES)(46), and the IQ jitter injection circuit (47) reside in the testhead (45).

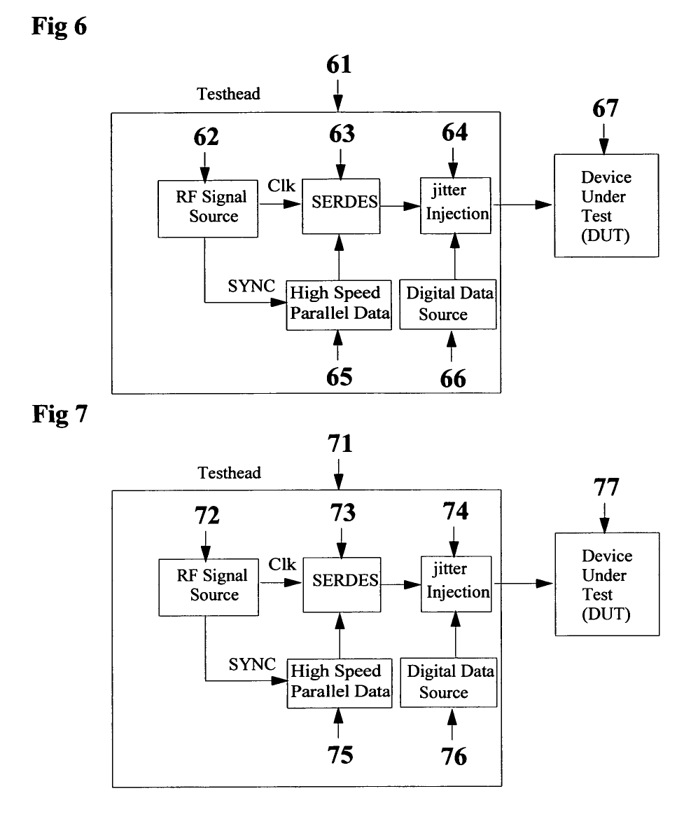

FIG. 5 shows a Serial data Test System comprising the Radio Frequency (RF) Signal Source (52), which is used as a low-jitter clock for the Parallel to Serial data converter (SERDES)(56) a high speed parallel data source (53) which is used to provide a high speed programmable parallel data stream which determines the final serial bit pattern in the Parallel to Serial data converter (SERDES)(46). In this example the Radio Frequency (RF) Signal Source (52), and the high speed parallel data source (53), all reside in the mainframe (51), whereas the Parallel to Serial data converter (SERDES)(56).IQ jitter injection circuit (57) residing in the testhead (55). FIG. 6 Shows another possible way of using the jitter injection in a test system. In this case the main component pieces all reside in the testhead (61). This has the advantage of shorter cable lengths and electrical delays which at high speed can be significant. Here the the Radio Frequency (RF) Signal Source (62), which is used as a low-jitter clock for the Parallel to Serial data converter (SERDES)(64) a high speed parallel data source (65) which is used to provide a high speed programmable parallel data stream which determines the final serial bit pattern in the Parallel to Serial data converter (SERDES)(64). A digital data source (66) can be used to controls the IQ jitter injection circuit (64). In this example the Radio Frequency (RF) Signal Source (62), the high speed parallel data source (65), digital data source (66), the Parallel to Serial data converter (SER-DES)(63), and the IQ jitter injection circuit (64) reside in the testhead (61).

FIG. 7 Shows another possible way of using the jitter injection in a test system. In this case the main component pieces all reside in the testhead (71). This has the davantage of shorter cable lengths and electrical delays which at high speed can be significant. Here the the Radio Frequency (RF) Signal Source (72), which is used as a low-jitter clock for the Parallel to Serial data converter (SERDES)(74) a high speed parallel data source (75) which is used to provide a high speed programmable parallel data stream which determines the final serial bit pattern in the Parallel to Serial data converter (SERDES)(64). In this case no digital data source is required because the IQ jitter injection circuit (74) generates it's own jitter patterns internally. In this example the Radio Frequency (RF) Signal Source (72), the high speed parallel data source (75), digital data source (76), the Parallel to Serial data converter (SERDES)(73), and the IQ jitter injection circuit (74) reside in the testhead (71).

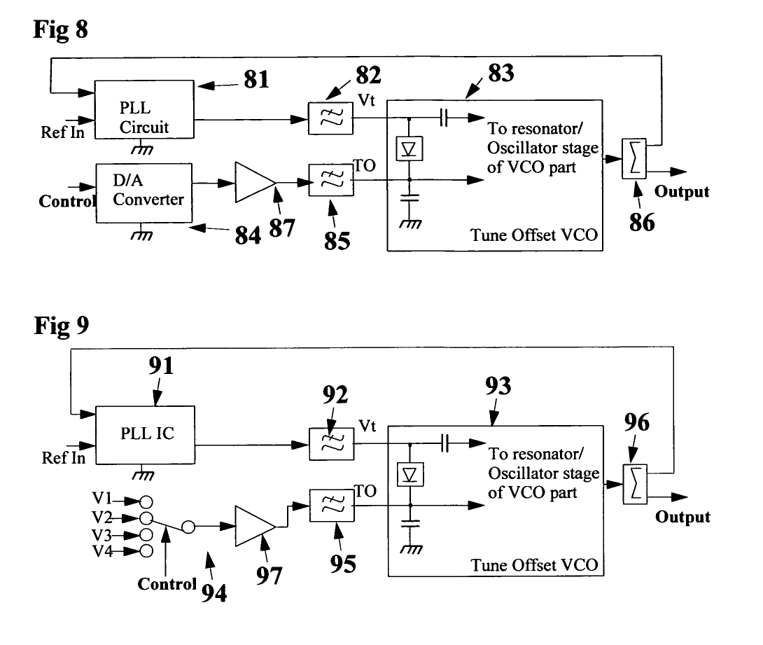

FIG. 8 shows an example of a phase-locked loop (PLL) circuit using the switched-offset phase locked loop for low noise applications technique. The heart of this circuit is the switched-offset-Voltage Controlled Oscillator (VCO)(83), this produces an extremely low phase noise and low jitter RF signal which is fed to a splitter (86). Part of the signal goes to the output where it may undergo further signal conditioning like filters, amplifiers or attenuators. The rest of the signal is fed to the phase-locked loop (PLL) circuit (81), here it is compared to incoming reference and an error signal generated which is fed via the loop filter (82) to the switched-offset Voltage Controlled Oscillator (VCO)(83) tune voltage input, thus completing the loop. The phase-locked loop (PLL) circuit (81) could be a fractional or integer phase-locked loop circuit, integrated circuit, or even a simple phase comparator. On the lower side of FIG. 8 a DC control voltage is required, tin this example it is produced by a D/A converter, the purpose of this voltage is to provide a low noise DC bias for the varactor diode low side for the switched-offset Voltage Controlled Oscillator (VCO)(83), this may be amplified (87), and/or filtered (85) to get the required control voltage range with a very low noise. The purpose of this control voltage is to effectively set the tune range of the Voltage controlled Oscillator (VCO) so for example if the full tune voltage were 18 volts and phase-locked loop (PLL) circuit (81) had an output range of 0 to 4.5 Volts then to enable the switched-offset Voltage Controlled Oscillator (VCO)(83) to cover it's entire tune range this circuit would require a control bias at least in the range of 0 to −13.5 Volts. If a smaller switched-offset Voltage Controlled Oscillator (VCO)(83) tune range were required then the DC bias would be scaled appropriately. The difference between the switched-offsetVoltage Controlled Oscillator (VCO)(83) and a conventional Voltage Controlled Oscillator (VCO) is that the ground return instead of being tied directly to ground is AC coupled to ground via a broadband DC blocking capacitor (86). This enables a DC offset to be applied to the low side of the varactor meaning that a lower control voltage can be used on the VCO high side. The advantage of this being that high tuning voltage Voltage Controlled Oscillator (VCO)s with their inherently lower phase noise can be used, but driven from a low voltage phase-locked loop device without the need for loop amplifiers which add noise to the system.

FIG. 9 shows an example of a phase-locked loop (PLL) circuit using the switched-offset phase locked loop for low noise applications technique. The heart of this circuit is the switched-offset-Voltage Controlled Oscillator (VCO)(93), this produces an extremely low phase noise and low jitter RF signal which is fed to a splitter (96). Part of the signal goes to the output where it may undergo further signal conditioning like filters, amplifiers or attenuators. The rest of the signal is fed to the phase-locked loop (PLL) circuit (91), here it is compared to incoming reference and an error signal generated which is fed via the loop filter (92) to the switched-offset Voltage Controlled Oscillator (VCO)(93) tune voltage input, thus completing the loop. The phase-locked loop (PLL) circuit (91) could be a fractional or integer phase-locked loop circuit, integrated circuit, or even a simple phase comparator. On the lower side of FIG. 9 a DC control voltage is required, tin this example it is produced by a switched resistor network (94), this is potentially even lower noise than the previous example. The purpose of this voltage is again to provide a low noise DC bias for the varactor diode low side for the switched-offset Voltage Controlled Oscillator (VCO)(93), this may again be amplified (97), and/or filtered (95) to get the required control voltage range with a very low noise. The purpose of this control voltage is to effectively set the tune range of the Voltage controlled Oscillator (VCO) so for example if the full tune voltage were 18 volts and phase-locked loop (PLL) circuit (91) had an output range of 0 to 4.5 Volts then to enable the switched-offset Voltage Controlled Oscillator (VCO)(93) to cover it's entire tune range this circuit would require a control bias at least in the range of 0 to −13.5 Volts. If a smaller switched-offset Voltage Controlled Oscillator (VCO)(93) tune range were required then the DC bias would be scaled appropriately. The difference between the switched-offsetVoltage Controlled Oscillator (VCO)(93) and a conventional Voltage Controlled Oscillator (VCO) is that the ground return instead of being tied directly to ground is AC coupled to ground via a broadband DC blocking capacitor (96). This enables a DC offset to be applied to the low side of the varactor meaning that a lower control voltage can be used on the VCO high side. The advantage of this being that high tuning voltage Voltage Controlled Oscillator (VCO)s with their inherently lower phase noise can be used, but driven from a low voltage phase-locked loop device without the need for loop amplifiers which add noise to the system.

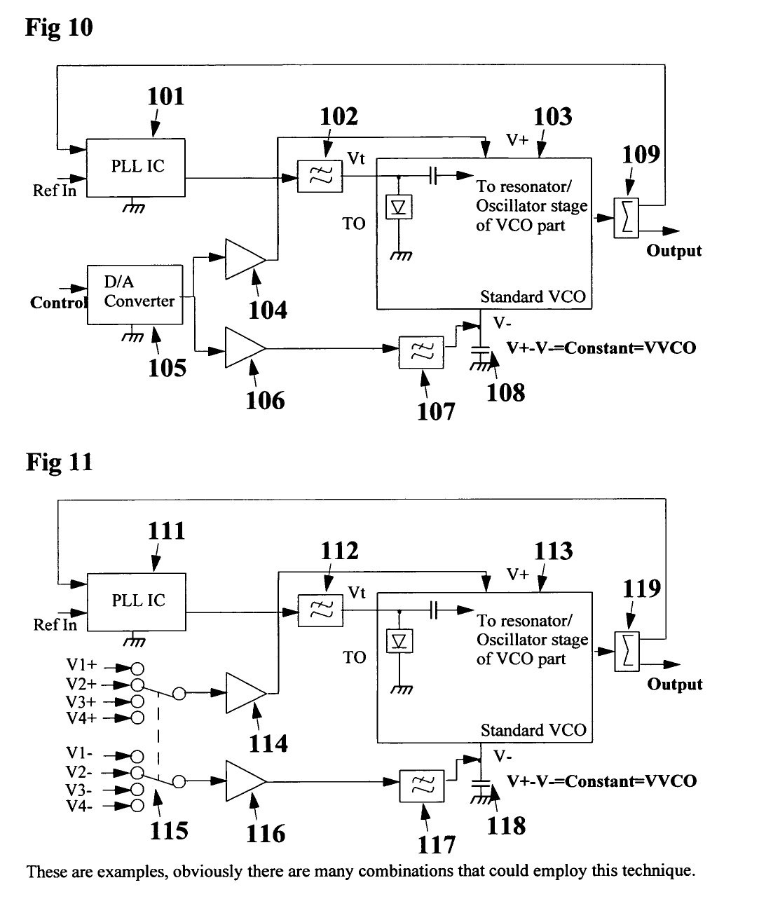

FIG. 10 shows an example of a phase-locked loop (PLL) circuit using the switched-offset phase locked loop for low noise applications technique with a sliding supply rail. This time a regular Voltage Controlled Oscillator (VCO)(103) is used and both the positive and supply ground are DC level-shifted to achieve the full Voltage Controlled Oscillator (VCO)(103) tune range. This again produces an extremely low phase noise and low jitter RF signal which is fed to a splitter (106). Part of the signal goes to the output where it may undergo further signal conditioning like filters, amplifiers or attenuators. The rest of the signal is fed to the phase-locked loop (PLL) circuit (101), here it is compared to incoming reference and an error signal generated which is fed via the loop filter (102) to the switched-offset Voltage Controlled Oscillator (VCO)(103) tune voltage input, thus completing the loop. The phase-locked loop (PLL) circuit (101) could be a fractional or integer phase-locked loop circuit, integrated circuit, or even a simple phase comparator. On the lower side of FIG. 10 a DC control voltage is required, tin this example it is produced by a Digital to Analog D/A converter (104). The purpose of this control voltage is to provide a low noise DC offset bias for the power supplies so that the varactor diode in the Voltage Controlled Oscillator (VCO)(103) can be tuned over it's full or required tune range. This bias voltage may be amplified (107), and/or filtered (105) to get the required control voltage range with a very low noise. The purpose of this control voltage is to effectively set the power supply DC offsets to cover the full tune range of the Voltage controlled Oscillator (VCO) so for example if the full Voltage Controlled Oscillator (VCO)(103) tune range was 18V to cover it's entire tune range and the Voltage Controlled Oscillator (VCO)(103) required a +18V supply then the positive supply would shift from +18 to +4.5 Volts and the negative supply would shift from 0V to at least −13.5 Volts. If a smaller switched-offset Voltage Controlled Oscillator (VCO)(103) tune range were required then the DC bias would be scaled appropriately. The advantage of this technique again being that high tuning voltage Voltage Controlled Oscillator (VCO)s with their inherently lower phase noise can be used, but driven from a low voltage phase-locked loop device without the need for loop amplifiers which add noise to the system.

FIG. 11 shows another example of a phase-locked loop (PLL) circuit using the switched-offset phase locked loop for low noise applications technique with a sliding supply rail. This time a regular Voltage Controlled Oscillator (VCO)(113) is used and both the positive and supply ground are DC level-shifted to achieve the full Voltage Controlled Oscillator (VCO)(113) tune range. This again produces an extremely low phase noise and low jitter RF signal which is fed to a splitter (116). Part of the signal goes to the output where it may undergo further signal conditioning like filters, amplifiers or attenuators. The rest of the signal is fed to the phase-locked loop (PLL) circuit (111), here it is compared to incoming reference and an error signal generated which is fed via the loop filter (112) to the switched-offset Voltage Controlled Oscillator (VCO)(113) tune voltage input, thus completing the loop. The phase-locked loop (PLL) circuit (111) could be a fractional or integer phase-locked loop circuit, integrated circuit, or even a simple phase comparator. On the lower side of FIG. 10 a DC control voltage is required, tin this example it is produced by a switched reference voltage network (114), this is potentially a lower noise technique than using a Digital to Analog Converter (DAC). The purpose of this control voltage is to provide a low noise DC offset bias for the power supplies so that the varactor diode in the Volt age Controlled Oscillator (VCO)(113) can be tuned over it's full or required tune range. This bias voltage may be amplified (117), and/or filtered (115) to get the required control voltage range with a very low noise. The purpose of this control voltage is to effectively set the power supply DC offsets to cover the full tune range of the Voltage controlled Oscillator (VCO) so for example if the full Voltage Controlled Oscillator (VCO)(1 13) tune range was 18V to cover it's entire tune range and the Voltage Controlled Oscillator (VCO)(113) required a +18V supply then the positive supply would shift from +18 to +4.5 Volts and the negative supply would shift from 0V to at least −13.5 Volts. If a smaller switched-offset Voltage Controlled Oscillator (VCO) tune range were required then the DC bias would be scaled appropriately. The advantage of this technique again being that high tuning voltage Voltage Controlled Oscillator (VCO)s with their inherently lower phase noise can be used, but driven from a low voltage phase-locked loop device without the need for loop amplifiers which add noise to the system.

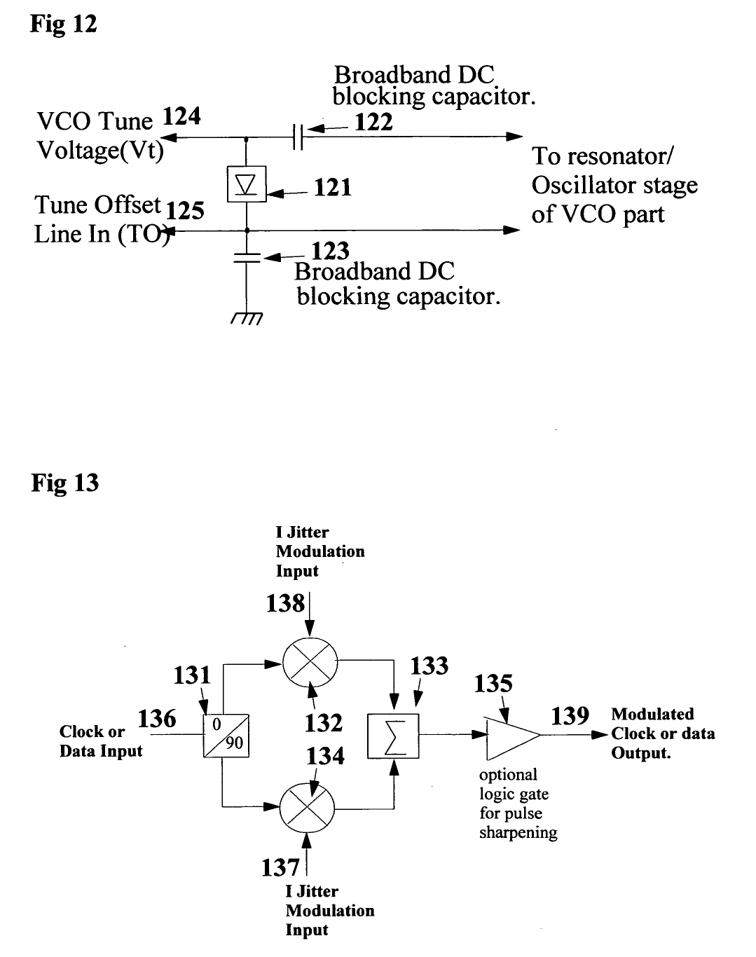

FIG. 12 shows one possible internal structure for a Switched-Offset Voltage Controlled Oscillator (VCO). Here there is a conventional varactor diode (121) with one side connected to the tune voltage input(124), the other is connected to the tune offset input (125). It is also connected to ground via a broadband DC blocking capacitor (123). The tune voltage from input (124) may be DC blocked from the rest of the Switched-Offset Voltage Controlled Oscillator (VCO) circuitry by broadband DC blocking capacitor (122). Other Voltage Controlled Oscillator (VCO) circuits may be adapted to this technique, it is the addition of this additional tune offset input (125) giving access to both sides of a tuning varactor that makes the difference between a switch-offset VCO and a regular VCO.

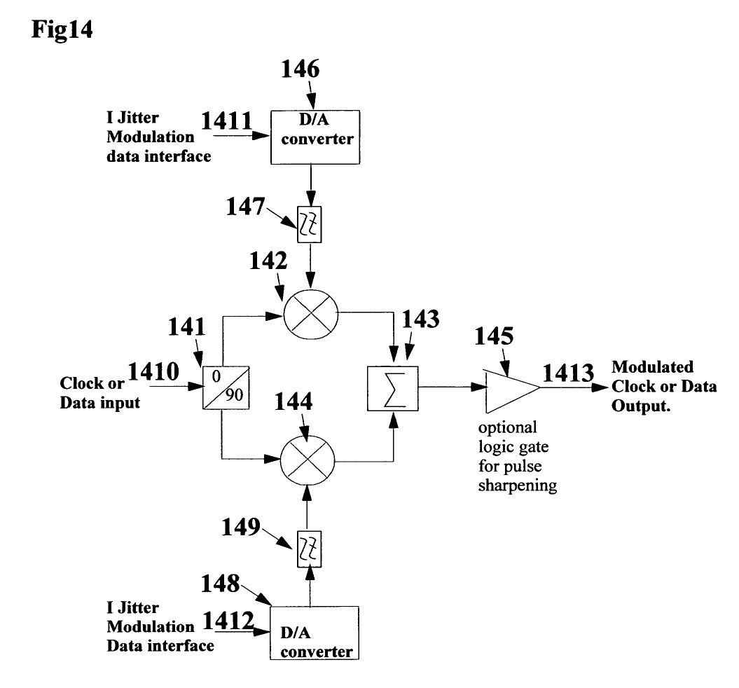

FIG. 13 shows an example of the basic jitter modulation circuit, a clock or data signal is applied to input 136, it is then fed to a quadrature phase splitter, the 0 degree phase shifted signal is fed to the I mixer (138), and the 90 degree phase shifted signal is fed to the Q mixer (137), at each mixer a control waveform can be applied (137) and (138), the resulting signal from each mixer is then re-combined via a combiner(133) resulting in a vector-modulated signal which is fed to the output (1313). By varying the gain and phase relationship of the I (137) and Q (138) inputs it is possible to vary the overall phase of the input by +/−180 degrees. When using this with a digital waveform it results in a phase shift of the rising and falling edges of the clock or data input. This translates to creating a time shift of jitter of the signal of +/−T/2 where T is the period of the incoming clock or data signal (136). There is nothing new about I/Q modulation of analog signals, however to use an I/Q modulator to modulate a digital signal thus producing precisely controllable jitter is entirely unique. Furthermore because IQ modulators are intended for Microwave and Radio Frequency (RF) applications they can easily function at very high speeds with frequency of operation ranging from Megahertz to tens of GigaHertz, and modulating bandwidths of hundreds of MegaHertz. Using this technique it is possible to achieve very precise jitter injection for clock or serial data well up into the high GigaBit/Second ranges. Furthermore the signal could be switched between a number of such I-Q modulators of different frequency capabilities to achieve a broader modulation frequency range, or cascaded to achieve higher jitter capabilities.

FIG. 14 shows another example of the basic jitter modulation circuit, again a clock or data signal is applied to input 146, it is then fed to a quadrature phase splitter, the 0 degree phase shifted signal is fed to the I mixer (148), and the 90 degree phase shifted signal is fed to the Q mixer (147), at each mixer a control waveform is applied via D/A converters (146) and (148), in each case these signal are filtered by their respective low pass filters (147) and (149) to each mixer. The resulting signal from each mixer is then re-combined via a combiner(143) resulting in a vector-modulated signal. By varying the gain and phase relationship of the I (1411) and Q (1412) inputs it is possible to vary the overall phase of the input by +/−180 degrees. When using this with a digital waveform it results in a phase shift of the rising and falling edges of the clock or data input. This translates to creating a time shift of jitter of the signal of +/−T/2 where T is the period of the incoming clock or data signal (146) and the resulting signal is at the output (1413)

1) A switched offset phase-locked loop (PLL) for use in generating either low phase noise Radio Frequency (RF) signals, and/or as a low jitter clock source for Data Communication useage comprising:
A Voltage Controlled Oscillator (VCO)
A phase locked Loop (PLL) circuit
A reference clock for the phase locked Loop (PLL)either external or internal to the circuit
A loop filter
A method of offsetting the Tune Voltage input to the Voltage Controlled Oscillator (VCO)

2) The Voltage Controlled Oscillator (VCO) of claim 1) wherein a tune offset line exists by which a DC offset can be applied to the input.

3) The phase locked loop circuit of claim 1 wherein any combination of the loop filter, the reference clock, the Voltage Controlled Oscillator (VCO), or a method of offsetting the Tune Voltage input to the Voltage Controlled Oscillator (VCO) is also incorporated into the said device.

4) The Reference clock of claim 1) wherein any combination of free running oscillator, other phase locked Loop (PLL) circuit(s), an oscillator that will free-run and synchronize with an external reference input, or a direct external reference input from an external frequency source is used.

5) A method for offsetting the Voltage Controlled Oscillator (VCO) tune voltage of claim 1 wherein the Voltage Controlled Oscillator (VCO) supply rails are shifted, a DC offset is provided to the voltage Controlled Oscillator(VCO) for the purpose of increasing it's tunable frequency range, or where other voltages within the circuit are shifted to achieve a DC offset on the Voltage Controlled Oscillator (VCO) input.

6) The switched offset phase-locked loop (PLL) of claim 1) wherein the circuit is a used as a stand-alone instrument, as part of a system or sub-system, as an instrument within the mainframe or enclosure of a larger tester, or as an instrument within the testhead of a Tester.

7) The switched offset phase-locked loop (PLL) of claim 1) wherein the offset is applied from a Digital to Analog (DAC) converter or switched voltage references.

8) A method of injecting precisely controlled Jitter into clock, data or digital circuitry using I/Q Modulation Techniques comprising:
A clock or data source
An IQ modulator
A method of simulataneously controlling the modulator I and Q inputs.

9) The clock or data source of claim 8) wherein alone or any combination of the low jitter clock of claim 1), data synchronous to the low jitter clock of claim 1) , or a clock and or from an external circuit or instrument, data from an external circuit or instrument, or any combination of the above.

10) The IQ Modulator of claim 8) wherein an integrated circuit (IC), module, discrete circuitry, or Digital Signal Processing/software techniques are used.

11) The method of simulataneously controlling the I and Q modulator inputs wherein any combination of Digital to Analog converter (DAC), linear control voltages, external inputs, or sample and hold techniques are used.
